(19) United States
(12) Patent Application Publication
(10) Pub. No.: US 2026/0130163 A1
(43) Pub. Date: May 7, 2026

(54) ETCHING SYSTEM AND ETCHING METHOD

(71) Applicant: NANYA TECHNOLOGY CORPORATION, NEW TAIPEI CITY (TW)

(72) Inventor: TSE-YAO HUANG, NEW TAIPEI CITY (TW)

(21) Appl. No.: 18/934,443

(22) Filed: Nov. 1, 2024

(51) Int. Cl. H01L 21/67; G05B 13/02; H01J 37/32; H01L 21/3065; H01L 21/66; H01L 21/683

(52) U.S. Cl. CPC H10P 72/0604; G05B 13/0265; H01J 37/32724; H01J 37/32935; H10P 50/242; H10P 72/0421; H10P 72/722; H10P 74/23; H01J 2237/2007; H01J 2237/334

(57) ABSTRACT

The present application discloses an etching system. The etching system includes a process chamber, an image and temperature control device, and an artificial intelligence control module. The process chamber is configured to execute an etching process based on a first etching recipe on a first wafer. The image and temperature control device is configured to generate a thermal image of the first wafer during the etching process. The artificial intelligence control module is configured to determine whether the thermal image is compliant with a predetermined requirement. When the thermal image is not compliant with the predetermine requirement, the artificial intelligence control module is configured to update the first etching recipe according to the plurality of parameters so as to generate a second etching recipe.

### TECHNICAL FIELD

The present disclosure relates to an etching system and an etching method, and more particularly, to an etching system and an etching method using an artificial intelligence control module.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Furthermore, the temperature variation can cause rick of wafer breaking especially to the thinner wafer or wafer having the scaling-down process. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides an etching system. The etching system includes a process chamber, an image and temperature control device, and an artificial intelligence control module. The process chamber is configured to execute an etching process based on a first etching recipe on a first wafer. The image and temperature control device is configured to generate a thermal image of the first wafer during the etching process. The artificial intelligence control module is configured to determine whether the thermal image is compliant with a predetermined requirement. When the thermal image is not compliant with the predetermine requirement, the artificial intelligence control module is configured to update the first etching recipe according to the plurality of parameters so as to generate a second etching recipe.

Another aspect of the present disclosure provides an etching method. The etching method includes: obtaining a thermal image of a first wafer; performing an etching process on the first wafer based on a first etching recipe; determining, by an artificial intelligence control module, whether the thermal image is compliant with a predetermined requirement; when the thermal image is not compliant with the predetermined requirement, updating the first etching recipe to generate a second etching recipe by the artificial intelligence control module according to the thermal image; and performing the etching process on a second wafer based on the second etching recipe.

Due to the usage of artificial intelligence control module, the temperature of the wafer can be controlled more precisely and timely. As a result, the yield and/or reliability of the wafers may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic diagram of an etching system in accordance with some embodiments of the present disclosure.

FIG. 2 is a schematic diagram of a process chamber in accordance with some embodiments of the present disclosure.

FIG. 3 is a schematic diagram of an electroadhesion between a wafer and an electrostatic chunk in accordance with some embodiments of the present disclosure.

FIG. 4 is a schematic diagram of a process chamber in accordance with other embodiments of the present disclosure.

FIG. 5 is a schematic diagram of an electroadhesion between a wafer and an electrostatic chunk in accordance with other embodiments of the present disclosure.

FIG. 6 and FIG. 7 are schematic diagrams of an electroadhesion between a wafer and an electrostatic chunk in accordance with various embodiments of the present disclosure.

FIG. 8 is a flow chart of an etching method in accordance with some embodiments of the present disclosure

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

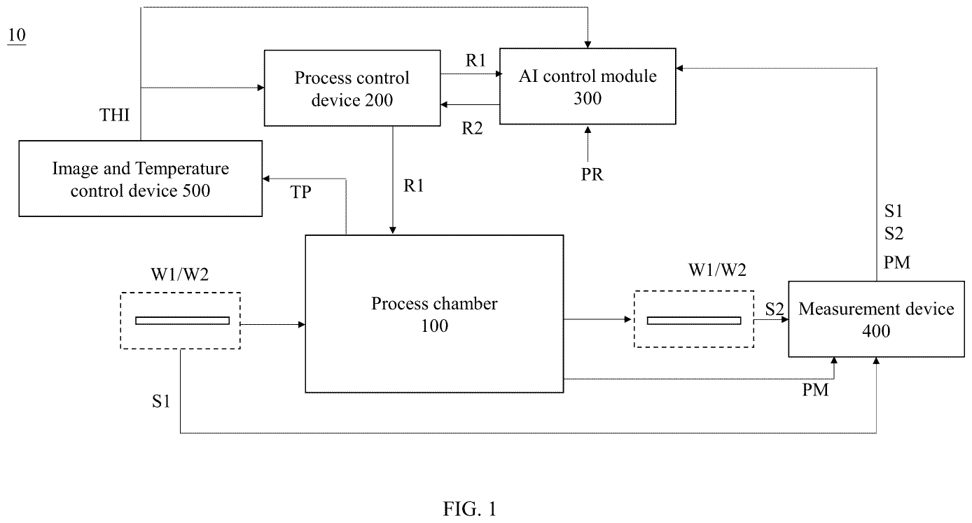

FIG. 1 is a schematic diagram of an etching system 10 in accordance with some embodiments of the present disclosure. The etching system 10 includes a process chamber 100, a process control device 200, an artificial intelligence (AI) control module 300, a measurement device 400, and an image and temperature control device 500.

The etching system 10 is configured to execute an etching recipe R1 on a wafer W1. Specifically, the etching system 10 is configured to perform an etching process on the wafer W1 based on the etching recipe R1, and a state of the wafer W1 will change from a first state S1 to a second state S2 accordingly. In this embodiment, the first state S1 indicates that the state of the wafer W1 before being etched, and the second state S2 indicates that the state of the wafer W1 after being etched. In some embodiments, the etching recipe R1 is stored in the process control device 200, and the etching recipe R1 is acquired by the process chamber 100 when the process chamber 100 is going to process the wafer W1. In some embodiments, the etching recipe R1 is given. In some embodiments, the etching recipe R1 is generated by the AI control module 300.

The wafer W1 is transferred into the process chamber 100 and etched in the process chamber 100. Although merely one wafer W1 is illustrated in FIG. 1, multiple wafers may be processed grouped in lots, as such, the reference to a wafer in the singular in the present embodiment does not by necessity limit the disclosure to a single wafer, but may be illustrative of a lot including a plurality of wafers, a plurality of lots, or any such grouping of material.

In some embodiments, the wafer W1 may be at the stage of front-end-of-line such as forming the word lines, forming the gate structure, forming the contact, but are not limited thereto. In some embodiments, the wafer W1 may be at the stage of back-end-of-line such as forming the plugs, or forming top metals, or forming the capacitors, but are not limited thereto.

In some embodiments, the etching system 10 may include one or more process chambers 100 that are not separately illustrated. The wafer W1 may be placed in the process chamber 100, and then may be subjected to the etching process employing the etching recipe. In some embodiments, the etching recipe R1 may be a nominal recipe.

In some embodiments, the process control device 200 may include a graphic user interface (GUI) component (not shown for clarity) and a database (not shown for clarity). The GUI component may be provided that enable users to: view chamber status; create and edit x-y charts of summary and raw (trace) parametric data for selected wafer; view chamber alarm logs; configure data collection plans that specify conditions for writing data to the database or to output files; input files to statistical process control (SPC) charting, modeling and spreadsheet programs; examine wafer processing information for specific wafer, and review data that is currently being saved to the database; create and edit SPC charts of process parameters, and set SPC alarms which generate email warnings; run multivariate principal component analysis (PCA) and/or partial least squares (PLS) models; and/or view diagnostics screens in order to troubleshoot and report problems with the process chamber 100.

In some embodiments, raw data and trace data from the process control device 200 may be stored as files in the database. The amount of data may depend on the data collection plans configured by the user, as well as the frequency with which processes are performed and which process chambers 100 are run. The data obtained from the process control device 200 may be stored in tables. In some embodiments, the GUI component and the database of the process control device 200 may not be required. In some embodiments, the process chamber 100 are the process control device 200 are integrated as a single device.

In some embodiments, the AI control module 300 is coupled to the process control device 200. In some embodiments, the AI control module 300 and the process control device 200 are independent elements which physically separate from each other. The communication between the AI control module 300 and process control device 200 in the etching system 10 may use any suitable communication technologies, such as analog technologies (e.g., relay logic), digital technologies (e.g., RS232, Ethernet, or wireless), network technologies (e.g., local area network (LAN), a wide area network (WAN), the Internet), Bluetooth technologies, Near-field communication technologies, and/or any other suitable communication technologies. The communication between the AI control module 300 and other devices in the etching system 10 is compliant with the general equipment module/semiconductor equipment communications standard (GEM SECS) communications protocol.

In other embodiments, the AI control module 300 is integrated in the process control device 200. In alternative embodiments, the AI control module 300 is integrated in the process chamber 100.

The AI control module 300 and the measurement device 400 are independent elements which physically separate from each other. The communication between the artificial intelligence module 300 and the measurement device 400 can use any suitable communication technologies, such as analog technologies (e.g., relay logic), digital technologies (e.g., RS232, Ethernet, or wireless), network technologies (e.g., local area network, a wide area network, the Internet), Bluetooth technologies, Near-field communication technologies, and/or any other suitable communication technologies. The communication between the AI control module 300 and the measurement device 400 is compliant with the general equipment module/semiconductor equipment communications standard communications protocol.

In some embodiments, the AI control module 300 may operate as a single input single output (SISO) device, as a single input multiple output (SIMO) device, as a multiple input single output (MISO) device, and as a multiple input multiple output (MIMO) device.

In some embodiments, the AI control module 300 may include any suitable hardware (which can execute software or application in some embodiments), such as, for example, computers, microprocessors, microcontrollers, application specific integrated circuits (ASICs), field-programmable gate arrays (FGPAs), and digital signal processors (DSPs) (any of which can be referred to as a hardware processor), encoders, circuitry to read encoders, memory devices (including one or more EPROMS, one or more EEPROMs, dynamic random access memory (“DRAM”), static random access memory (“SRAM”), and/or flash memory), and/or any other suitable hardware elements.

In some embodiments, the AI control module 300 may include a GUI component (not shown for clarity) and a database (not shown for clarity). The GUI component of the AI control module 300 may provide means of interaction between the AI control module 300 and a user. Authorized users and administrators may use the GUI component to modify the configuration and default parameters of the AI control module 300. Configuration data may be stored in the database.

In some embodiments, the GUI component of the AI control module 300 may include a status component for displaying the current status of the AI control module 300. In addition, the status component may include a charting component for presenting system-related and process-related data to a user using one or more different types of charts.

In some embodiments, the database of the AI control module 300 may be used for archiving input and output data. For example, the AI control module 300 may archive received inputs, sent outputs, and actions taken by the AI control module 300 in a searchable database.

In some embodiments, the AI control module 300 may include means for data backup and restoration. Also, the searchable database can include model information, configuration information, and historical information, and the AI control module 300 may use the database component to backup and restore model information and model configuration information both historical and current.

In some embodiments, the AI control module 300 may include a number of applications including at least one tool-related application, at least one module-related application, at least one sensor-related application, at least one interface-related application, at least one database-related application, at least one GUI-related application, and/or at least one configuration application.

In some embodiments, the AI control module 300 may include algorithms including one or more of the following, alone or in combination: machine learning, hidden Markov models; recurrent neural networks; convolutional neural networks; Bayesian symbolic methods; general adversarial networks; support vector machines; and/or any other suitable artificial intelligence algorithm.

In some embodiments, the AI control module 300 may include at least one process model which can predict the second state S2 of the wafer W1. For example, a process model for etch rate may be used along with a processing time to compute an etch depth, and a process model for deposition rate may be used along with a processing time to compute a deposition thickness. In some embodiments, the process model may include SPC charts, PLS models, PCA models, fault detection/correction (FDC) models, and multivariate analysis (MVA) models. In some embodiments, the AI control module 300 may receive and utilize externally data provided by the process control device 200 and the measurement device 400 for process parameter limits. For example, the GUI component of the AI control module 300 may provide a means for the manual input of the process parameter limits.

In some embodiments, the AI control module 300 may be used to configure any number of process modules. The AI control module 300 may collect, provide, process, store, and display data from processes involving the process control device 200 and/or the measurement device 400.

In some embodiments, the measurement device 400 is configured to measure a set of data of the wafer W1 so as to generate the first state S1 and the second stage S2. Specifically, the measurement device 400 measures the wafer W1 to generate the first state S1 before the process chamber 100 performs the etching recipe R1 on the wafer W1, and then the measurement device 400 measures the wafer W1 to generate the second state S2 after the process chamber 100 performs the etching recipe R1 on the wafer W1. In some embodiments, the first state S1 and the state S2 are transmitted to the AI control module 300. In some embodiments, the first state S1 is given without measurement.

In some embodiments, the measurement device 400 includes an after-etching-inspection (AEI) metrology tool. The AEI metrology tool may inspect and check for defects, contamination, and critical dimension (CD) following the etching process. In some embodiments, the measurement device 400 may include an optical spectrum (e.g., optical critical dimension or OCD) metrology tool to measure CD and/or profiles of etched features.

In some embodiments, the measurement device 400 may include a chip probe configured to measure electrical characteristics. For example, the chip probe may measure the leakage current, by resistance, of a gate, but is not limited thereto.

In some embodiments, the measurement device 400 may include a wafer acceptance test module (WAT) module configured to measure electrical characteristics. For example, the WAT module may measure the current, by resistance, of a gate, or the leakage current, by resistance, of a drain of a transistor, but is not limited thereto.

In some embodiments, the measurement device 400 may include a statistical process control (SPC) module configured to provide data related to profile (or topography) of a layer. For example, the SPC module may provide data related to profile (or topography) of a tungsten layer of a word line or the thickness variation of a gate oxide layer, but is not limited thereto.

The image and temperature control device 500 is configured to generate a thermal image THI of the wafer W1 during the etching process. Specifically, the image and temperature control device 500 is configured to obtain temperature information TP of the wafer W1 from the process chamber 100, and generate the thermal image THI of the wafer W1 according to the temperature information TP. In some embodiments, the thermal image THI indicates the temperature distribution profile of the wafer W1.

The thermal image THI is transmitted to the process control device 200 and the AI control module 300. The thermal image THI may be stored in the database of the process control device 200. The thermal image THI, the first state S1, and the second state S2 of the wafer W1 are analyzed by the AI control module 300, and the AI control module 300 is further configured to determine whether the second state S2 and/or the thermal image THI of the wafer W1 is compliant with a predetermined requirement PR (e.g., an acceptance criteria or a specification). In some embodiments, the predetermined requirement PR is a user input data.

When the second state S2 is not compliant with the predetermined requirement PR, the AI control module 300 may update the etching recipe R1 according to the second state S2 and the thermal image THI to provide an updated etching recipe to the process control device 200 for the next wafer. To facilitate understanding, the next wafer is also referred to as the wafer W2, and the updated etching recipe is also referred to as an etching recipe R2, in which the etching recipe R2 is different from the etching recipe R1. The wafer W2 will go through the etching process based on the etching recipe R2, and the wafer W2 will have the first state S1, the second S2, and the thermal image THI as well.

When the thermal image THI is not compliant with the predetermined requirement PR, the AI control module 300 may update the temperature control parameters to adjust the temperature of the wafer W1. The temperature control parameters will be discussed later. In some embodiments, when the thermal image THI shows that the temperature of the wafer W1 is not evenly distribution among the entire wafer W1, the AI control module 300 determines that the thermal image THI is not compliant with the predetermined requirement PR. In some embodiments, when a temperature offset between any two regions of the wafer W1 exceeds a predetermined value, the AI control module 300 determines that the thermal image THI is not compliant with the predetermined requirement PR. In some embodiments, when the temperature of a region of the wafer W1 is out of an allowable range (higher than a maximum limit or lower than a minimum limit), the AI control module 300 determines that the thermal image THI is not compliant with the predetermined requirement PR.

In some embodiments, when the thermal image THI is not compliant with the predetermined requirement PR, the wafer W1 may have risk of damage. The AI control module 300 is used to prevent the risk of damage. Therefore, the yield of the wafer W1 can be increased.

The measurement device 400 may be integrated within the process chamber 100. In some embodiments, the measurement device 400 may include a set of sensors which can monitor process-related parameters such as gas flow, gas ratio, or other applicable process-related parameters. Those parameters are collectively designated as parameters PM. The measurement device 400 is configured to transmit parameters PM to the AI control module 300 in a real time manner. In some embodiments, when the second state S2 is not compliant with the predetermined requirement PR, the AI control module 300 is further configured to analyze the parameters PM to generate the etching recipe R2. In some embodiments, the parameters PM includes, but not limit to, gas ratio, flow rate, tilt angle, and driving voltage. In contrast, when the second state S2 is compliant with the predetermined requirement PR, the etching recipe R1 may be kept and be applied to the wafer W2. In other words, the etching recipe R1 may be immediately updated or adjusted within a wafer-to-wafer time frame.

In some embodiments, the parameters PM are associated with the etching recipe R1 and stored in the process control device 200. The process control device 200 transmits the parameters PM to the process chamber 100 so as to make the process chamber 100 executes the etching recipe R1. However, the parameters PM may have subtle offset when the process chamber 100 performs the etching process due to some non-ideal factors. Therefore, the parameters PM obtained by the measurement device 400 can faithfully effect the real situation of the etching process.

In some embodiments, the AI control module 300 may use the parameters PM to compute process deviations. The process deviations may be used to determine a correction to the etching recipe R1 so as to generate the etching recipe R2 for the wafer W2 to be processed.

In some embodiments, the AI control module 300 may use table-based and/or formula-based techniques. For example, the recipes may be in a table, and the AI control module 300 does a table lookup to determine which correction or corrections provide the best solutions. Alternately, the corrections may be determined using a set of formulas, and the AI control module 300 determines which correction formula or corrections formulas provide the best solutions.

When the AI control module 300 uses table-based techniques, the feedback control variables are configurable. For example, a variable can be a constant or coefficient in the table. In addition, there can be multiple tables, and rule-based switching can be accomplished based on an input range or an output range.

When the AI control module 300 uses formula-based control, the feedback control variables are configurable. For example, a variable can be a constant or coefficient in the formula. In addition, there can be multiple formula combinations, and rule-based switching can be accomplished based on an input range or an output range.

In the present embodiment, after the etching process is performed, a following process is performed to the wafer W1, in which the following process may be a clean process, a deposition process, or other applicable processes.

By employing the AI control module 300, the related process recipe (e.g., the etching recipe in the present embodiment) may be updated (or adjusted) online. The next wafer (i.e., the wafer W2) may employ the updated (or adjusted) recipe so as to obtain second state S2 compliant with the acceptance criteria. As a result, the overall yield and/or reliability of the wafers may be improved.

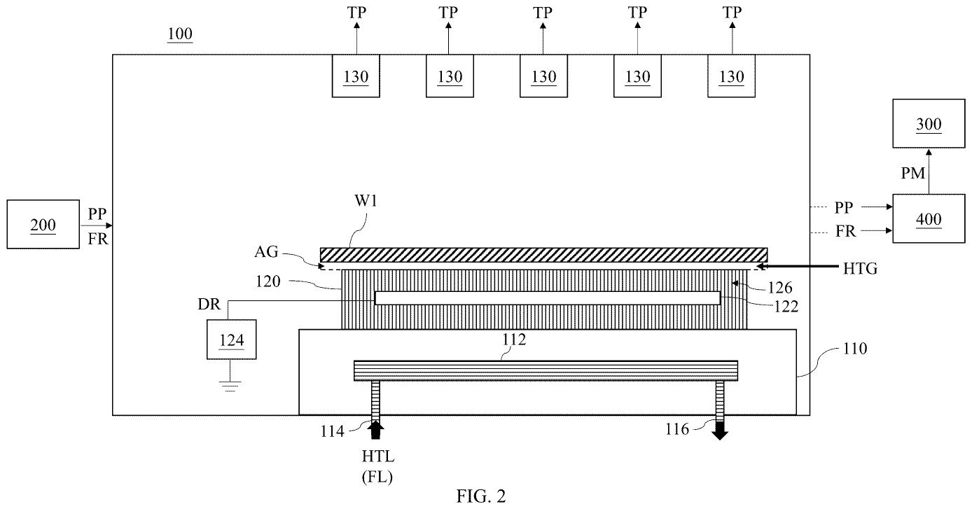

FIG. 2 is a schematic diagram of the process chamber 100 in accordance with one embodiment of the present disclosure. The process chamber 100 includes a pedestal 110, an electrostatic chuck (ESC) 120, and thermal sensors 130.

The pedestal 110 is configured to be a base to support the ESC 120 and the wafer W1. The ESC 120 is disposed on the pedestal 110 and configured to adhere the wafer W1 during the etching process via an electroadhesion between the ESC 120 and the wafer W1. The electroadhesion is created by applying a voltage DR on an electrode 122 of the ESC 120. The voltage DR is provided by a voltage provider 124.

The ESC 120 includes a dielectric body 126. The electrode 122 is buried in the dielectric body 126. When the voltage DR is applied on the electrode 122, the electrode 122 possesses an electric potential different from the ground, and the electric potential induces charges accumulating on a surface of the wafer W1 proximal to the ESC 120.

During the etching process, the wafer W1 may be heated due to ion impact or other reasons. When the temperature of the wafer W1 exceeds a threshold (or a range), the wafer W1 may be broken. The heat generated on the wafer W1 may also be transferred to the ESC 120 and the pedestal 110. Therefore, there are two mechanisms to maintain the temperature of the wafer W1 in the process chamber 100. The first mechanism is fluid mechanism, and the second mechanism is gas mechanism.

Regarding the fluid mechanism, the pedestal 110 includes a channel 112 for transmitting a heat transfer liquid HTL to bring the heat out of the pedestal 110 (or dissipate the heat to the pedestal 110). The heat transfer liquid HTL flows through the channel 112 to absorb the heat and bring the heat out of the pedestal 110 (or dissipate the heat to the pedestal 110). The heat transfer liquid HTL may be controlled to have a predetermined temperature. In some embodiments, the predetermined temperature may be a desired temperature of the wafer W1 during the etching process. When the temperature of the wafer W1 is different from the predetermined temperature, the heat transfer liquid HTL can provide or absorb the thermal energy to maintain the temperature of the wafer W1 in a desired state. The heat transfer liquid HTL is input to an inlet 114 of the channel 112 and output from an outlet 116 of the channel 112.

Regarding the gas mechanism, an air gap AG exists between the wafer W1 and the ESC 120 for transmitting a heat transfer gas HTG to take the heat away from the wafer W1 (or provide heat to the wafer W1). The heat transfer gas HTG is purged into the air gap AR and heated (or cooled down) by the wafer W1, then the heat transfer gas HTG escapes from the air gap AG. In some embodiments, the heat transfer gas HTG is also referred to as the backside heat transfer gas. In some embodiments, the heat transfer gas HTG includes noble gas. In some embodiments, the heat transfer gas HTG includes Helium (He).

The thermal sensors 130 are disposed over the ESC 120. When the wafer W1 is disposed on the ESC 120, the thermal sensors 130 are able to sense the temperature of the wafer W1 to generate the temperature information TP. Each thermal sensor 130 is configured to sense the temperature of a region of the wafer W1, and each region is located below the corresponding one of the thermal sensors 130. In other words, each temperature information TP indicates the temperature of the corresponding region of the wafer W1. Further, the thermal sensors 130 are configured to transmit the temperature information TP to the image and temperature control device 500. In some embodiments, the thermal sensors 130 are evenly distributed over the wafer W1. In some embodiments, a distance between the wafer W1 and any one of the thermal sensors 130 is constant. In some embodiments, the thermal sensors 130 are thermal imaging infrared cameras. It should be noted that the quantity and the distribution of the thermal sensors 130 are provided for illustrative purposes and not intended to be limiting. For example, in various embodiments, the thermal sensors 130 are randomly distributed over the wafer W1.

A purge press PP of the heat transfer gas HTG and a flow rate FR of the heat transfer liquid HTL are controlled by the process control device 200, and are executed by the process chamber 100. The purge pressure PP and the flow rate FR are parameters stored in and provided by the process control device 200. The measurement device 400 is configured to monitor the purge press PP and the flow rate FR in a real time manner, and transmit the purge press PP and the flow rate FR to the AI control module 300. In some embodiments, the parameters PM includes the purge press PP and the flow rate FR.

In some embodiments, the AI control module 300 is further configured to analyze the thermal image THI, the purge press PP, and the flow rate FR to update the etching recipe R1 without concerning the second state S2. In some embodiments, the AI control module 300 updates the purge press PP and the flow rate FR according to the thermal image THI. For example, the AI control module 300 may transfer the thermal image THI to control signals corresponding to the regions of the wafers, respectively. Next, the control signals are transmitted to the process control device 200 and configured to control the gas purging and the liquid flowing. In these embodiments, voltage signals and/or current signals are used to be the control signals. In such embodiments, the thermal image THI, the purge press PP, and the flow rate FR can be obtained before the completion of the etching recipe R1. Namely, the AI control module 300 is able to adjust the etching recipe R1 and provide the updated recipe (i.e., the etching recipe R2) to the process control device 200 during performing the etching recipe R1. In such embodiments, the process control device 200 can instruct the process chamber 100 to use the etching recipe R2 for the wafer W2. It is beneficial to the etching system 10 with high throughput. More specifically, it is especially beneficial to the etching system 10 having tight period between performing the etching process to the wafer W1 and the Wafer W2.

The AI control module 300 is further configured to adjust the purge pressure PP and the flow rate FR. Therefore, the purge pressure PP and the flow rate FR are real-time controlled and adopted to any undesired event occurred during the etching process which can deviate the temperature profile of the wafer W1.

In some conventional approaches, the temperature profile of the wafer W1 in the process chamber 100 cannot be obtained. However, the temperature profile of the wafer W1 can reveal plenty of information, such as the risk caused by performing etching recipe R1. Furthermore, in these conventional approaches, the purge pressure and the flow rate are set as constants, these conventional approaches lack the ability to maintain the temperature profile of the wafer during the etching process.

Compared to the present disclosure, the temperature distribution profile of the wafer W1 can be obtained online, and the purge pressure PP and the flow rate FR can be controlled in the real-time manner. Hence, the temperature distribution profile of the wafer W1 can be monitored in real-time, and the chance to break the wafer W1 is decreased.

In some embodiments, the etching process may use plasma to etch the wafer W1. In some embodiments, the etching process is a reactive-ion etching (RIE). In the etching recipe R1 (or the etching recipe R2), the thermal sensors 130 sense the temperature of the wafer W1 at a time period when the plasma is not generated. In some embodiments, the thermal sensors 130 sense the temperature of the wafer W1 before the plasma is generated. In some embodiments, the thermal sensors 130 sense the temperature of the wafer W1 after the plasma is vanished. In some embodiments, the etching recipe R1 (or the etching recipe R2) has multiple stages which are separated by periods (also referred to as stable period) without generating the plasma, and the thermal sensors 130 sense the temperature of the wafer W1 at the stable period.

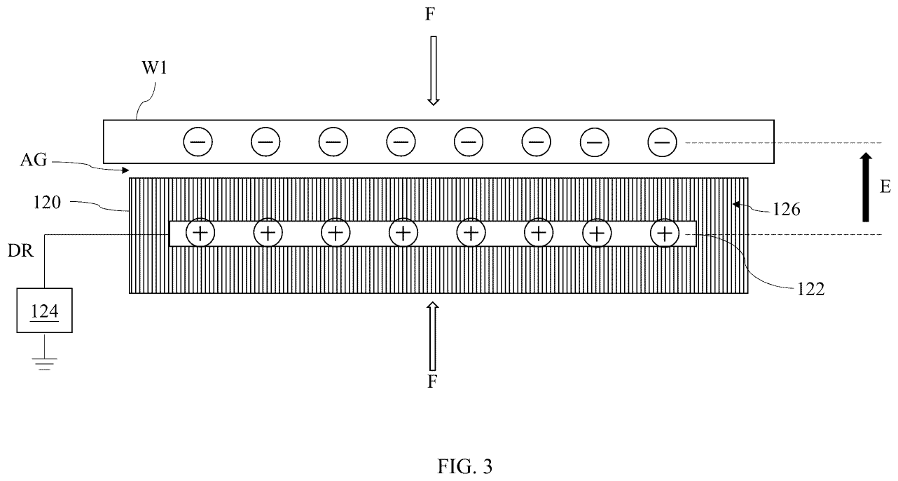

FIG. 3 is a schematic diagram of the electroadhesion between the wafer W1 and the ESC 120 in accordance with some embodiments of the present disclosure. In some embodiments, the voltage DR is positive to the ground. When the electrode 122 has the voltage DR, there is positive charge accumulated on the electrode 122, and the positive charge induces negative charge accumulated on the wafer W1 as shown in FIG. 3.

An electric field E exists between the ESC 120 and the wafer W1, and the electroadhesion is created according to the electric field E and the charges existing on the wafer W1 and the electrode 122. The electroadhesion provides a force F to the wafer W1 and the ESC 120 so as to keep the wafer W1 stay on the ESC 120.

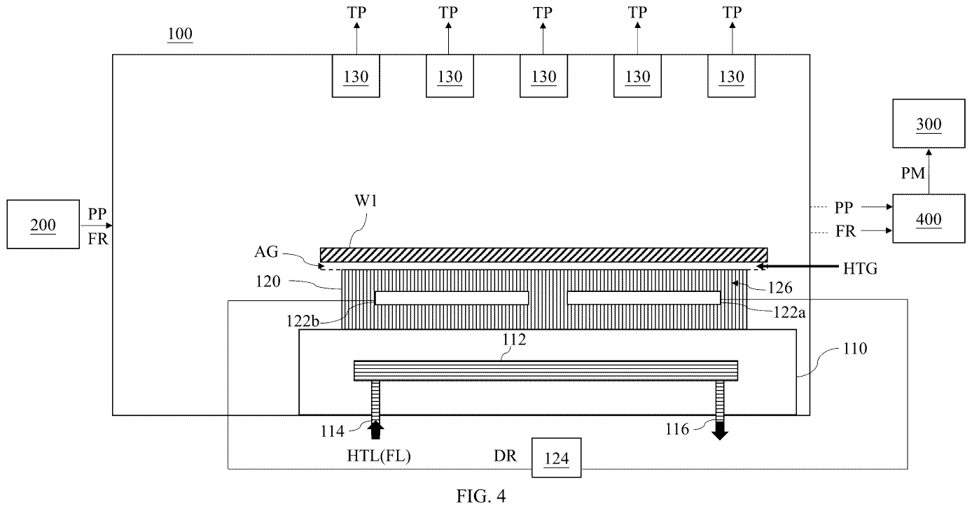

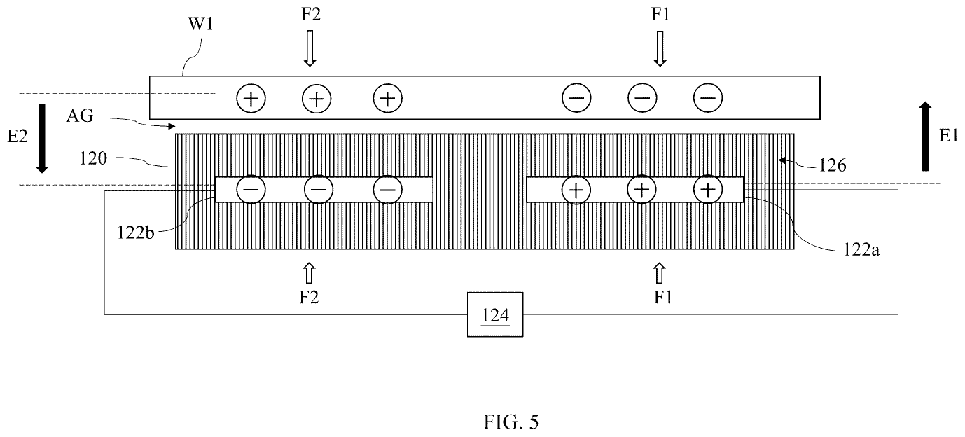

The ESC 120 shown in FIG. 2 and FIG. 3 is a unipolar ESC. However, the present disclosure is not limited there to the unipolar type. In other embodiments, the ESC 120 is bipolar ESC as illustrated in FIG. 4 and FIG. 5.

FIG. 4 is a schematic diagram of the process chamber 100 in accordance with other embodiments of the present disclosure. Compared to the ESC 120 shown in FIG. 2 and FIG. 3, the ESC 120 shown in FIG. 4 includes a first electrode 122a and a second electrode 122b instead of a single electrode 122. The first electrode 122a and the second electrode 122b are electrically separated. The voltage provider 124 is coupled between the first electrode 122a and the second electrode 122b, and configured to provide the voltage DR.

FIG. 5 is a schematic diagram of the electroadhesion between the wafer W1 and the ESC 120 in accordance with other embodiments of the present disclosure. When the voltage DR is applied between the first electrode 122a and the second electrode 122b, there is positive charge accumulated on the first electrode 122a, and negative charge accumulated on the second electrode 122b. The positive charge on the first electrode 122a induces negative charge accumulated on a portion of the wafer W1 above the first electrode 122a. Similarly, the negative charge on the second electrode 122b induces positive charge accumulated on another portion of the wafer W1 above the second electrode 122b.

An electric field E1 exists between the first electrode 122a and the portion of the wafer W1, and the electroadhesion is created according to the electric field E1 and the charges existing on the wafer W1 and the first electrode 122a. The electroadhesion provides a force F1 to the wafer W1 and the first electrode 122a so as to keep the wafer W1 stay on the ESC 120. Similarly, an electric field E2 exists between the second electrode 122b and the another portion of the wafer W1, and the electroadhesion is created according to the electric field E2 and the charges existing on the wafer W1 and the second electrode 122b. The electroadhesion provides a force F2 to the wafer W1 and the second electrode 122b so as to keep the wafer W1 stay on the ESC 120.

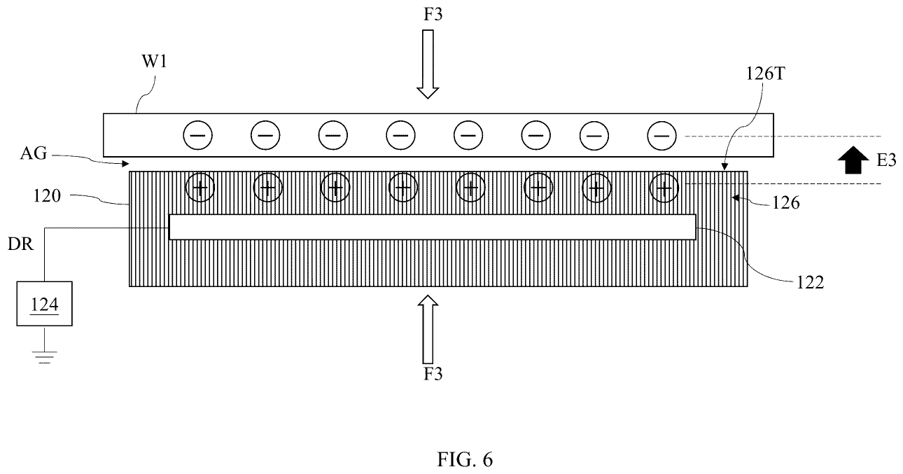

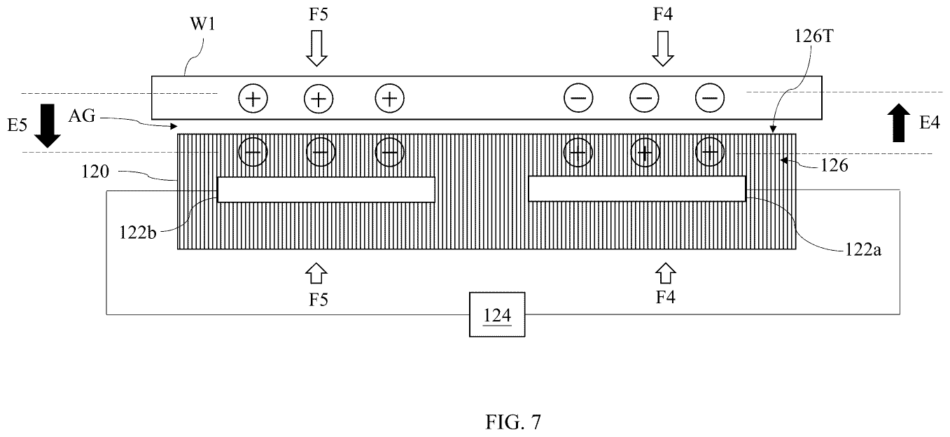

The ESC 120 shown in FIG. 3 and FIG. 5 is Coulumbic type ESC, in which the charge mainly accumulating on the electrode 122 (or on the first electrode 122a and the second electrode 122b). In various embodiments, the ESC can be Johnson-Rahbak type ESC as illustrated in FIG. 6 and FIG. 7.

Reference is made to FIG. 6 and FIG. 7. The Johnson-Rahbak type ESC 120 is illustrated according to various embodiments of the present disclosure. In FIG. 6, the charge on the unipolar type ESC 120 is accumulated on a top surface 126T of the dielectric body 126.

Compared to the Coulombic type ESC 120 shown in FIG. 3, a distance between the accumulated charge layers is shorter, therefore, an electric field E3 between the wafer W1 and the ESC 120 is greater than the electric field E. Accordingly, a force F3 driven by the electric field E3 is greater than the force F.

In FIG. 7, the charge on the bipolar type ESC 120 is accumulated on the top surface 126T of the dielectric body 126. Compared to the Coulombic type ESC 120 shown in FIG. 5, a distance between the accumulated charge layers is shorter, therefore, an electric field E4 and an electric field E5 between the wafer W1 and the ESC 120 is greater than the electric field E1 and the electric field E2. Accordingly, a force F4 driven by the electric field E4 and a force F5 driven by the electric field E5 are greater than the force F1 and the force F2.

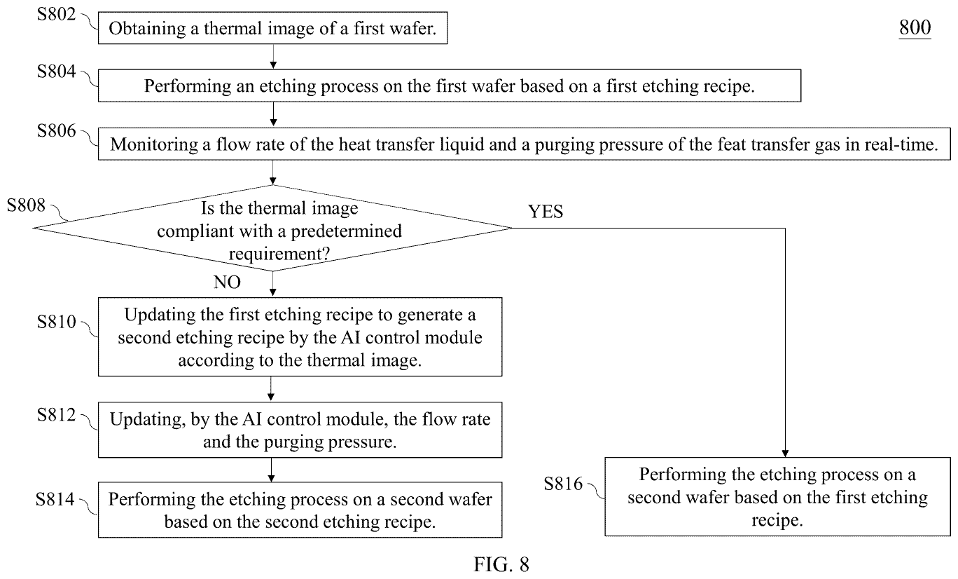

Reference is made to FIG. 8. FIG. 8 is a flow chart of an etching method 800 according to some embodiments of the present disclosure. In particular, the etching method 800 is able to control a temperature of a wafer during an etching process. The method includes operations S802, S804, S806, S808, S810, S812, S814, and S816. In some embodiments, the etching method 800 is performed by the etching system 10. To facilitate understanding, the etching method 800 is described with the etching system 10 and the reference numerals of the etching system 10 denoted in FIG. 1 to FIG. 7.

In operation S802, the thermal image THI of the wafer W1 is obtained. In operation S804, the etching process is performed on the wafer W1 based on the etching recipe R1. In operation S806, the flow rate FR of the heat transfer liquid HTL and the purging pressure PP of the heat transfer gas HTG are monitored in real-time.

In some embodiments, the flow rate and the purging pressure are continuously monitored. Namely, the monitoring is constantly performed during the etching method 800.

In operation S808, it is determined, by the AI control module 300, that whether the thermal image THI is compliant with the predetermined requirement PR. When the thermal THI is not compliant with the predetermined requirement PR, the etching method 800 is proceeded to operation S810. When the thermal image THI is compliant with the predetermined requirement PR, the etching method 800 is proceeded to operation S816.

In operation S810, the etching recipe R1 is updated to generate the etching recipe R2 by the AI control module 300 according to the thermal image THI.

In operation S812, the flow rate FR and the purging pressure PP are updated by the AI control module 300.

In operation S814, the etching process is performed on the wafer W2 based on the etching recipe R2.

When the thermal image THI is compliant with the predetermined requirement PR, the etching process is performed on the wafer W2 based on the etching recipe R1. Alternatively stated, when thermal image THI is compliant with the predetermined requirement PR, the next wafer (i.e., the wafer W2) is etched with the same etching recipe R1 as the previous wafer (i.e., the wafer W1).

One aspect of the present disclosure provides an etching system. The etching system includes a process chamber, an image and temperature control device, and an artificial intelligence control module. The process chamber is configured to execute an etching process based on a first etching recipe on a first wafer. The image and temperature control device is configured to generate a thermal image of the first wafer during the etching process. The artificial intelligence control module is configured to determine whether the thermal image is compliant with a predetermined requirement. When the thermal image is not compliant with the predetermine requirement, the artificial intelligence control module is configured to update the first etching recipe according to the plurality of parameters so as to generate a second etching recipe.

Another aspect of the present disclosure provides an etching method. The etching method includes: obtaining a thermal image of a first wafer; performing an etching process on the first wafer based on a first etching recipe; determining, by an artificial intelligence control module, whether the thermal image is compliant with a predetermined requirement; when the thermal image is not compliant with the predetermined requirement, updating the first etching recipe to generate a second etching recipe by the artificial intelligence control module according to the thermal image; and performing the etching process on a second wafer based on the second etching recipe.

Due to the usage of AI control module 300, the temperature of the wafers W1/W2 can be controlled more precisely and timely. As a result, the yield and/or reliability of the wafers may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. An etching system, comprising:
a process chamber, configured to execute an etching process based on a first etching recipe on a first wafer;
an image and temperature control device, configured to generate a thermal image of the first wafer during the etching process; and
an artificial intelligence (AI) control module, configured to determine whether the thermal image is compliant with a predetermined requirement, wherein when the thermal image is not compliant with the predetermine requirement, the AI control module is configured to update the first etching recipe according to a plurality of parameters so as to generate a second etching recipe.

2. The etching system of claim 1, wherein the AI control module is integrated in the process chamber.

3. The etching system of claim 1, wherein the process chamber comprises:
an electrostatic chunk (ESC), configured to adhere the first wafer via an electroadhesion;
a plurality of thermal sensors, configured to sense a plurality of temperature information of the first wafer, respectively; and
a pedestal, configured to support the ESC.

4. The etching system of claim 3, wherein the pedestal comprises:
a channel, configured to transmit a heat transfer liquid to control a temperature of the first wafer.

5. The etching system of claim 4, wherein a flow rate of the heat transfer liquid is monitored in real-time, and the flow rate is transmitted to the AI control module,
wherein when the thermal image is not compliant with the predetermine requirement, the AI control module updates the first etching recipe according the flow rate to generate the second etching recipe.

6. The etching system of claim 5, wherein when AI control module updates the first etching recipe, the AI control module is further configured to update the flow rate according to the thermal image.

7. The etching system of claim 3, wherein when the ESC adheres the first wafer, an air gap exists between the first wafer and the ESC,
wherein a heat transfer gas is purged into the air gap, wherein a purge pressure of the heat transfer gas is monitored in real-time, and the purge pressure is transmitted to the AI control module.

8. The etching system of claim 7, wherein when the thermal image is not compliant with the predetermine requirement, the AI control module updates the first etching recipe according the purge pressure.

9. The etching system of claim 8, wherein when AI control module updates the first etching recipe, the AI control module is further configured to update the purge pressure according to the thermal image.

10. The etching system of claim 3, wherein image and temperature control device is configured to obtain the plurality of temperature information so as to generate the thermal image.

11. The etching system of claim 3, wherein the plurality of temperature information indicate a temperature of a plurality of regions of the first wafer, respectively.

12. The etching system of claim 3, wherein the ESC comprises:
a dielectric body;
an electrode, buried in the dielectric body; and
a voltage provider, configured provide a voltage to the electrode,
wherein a first charge is accumulated on the electrode due to the voltage, and a second charge is induced by the first charge and accumulated on the first wafer.

13. The etching system of claim 3, wherein the ESC comprises:
a dielectric body;
a first electrode, buried in the dielectric body;
a second electrode, buried in the dielectric body and separated from the first electrode; and
a voltage provider, coupled between the first electrode and the second electrode, and configured provide a voltage between the first electrode and the second electrode,
wherein a first positive charge and a first negative charge are accumulated on the first electrode and the second electrode due to the voltage, respectively,
wherein a second negative charge is induced by the first positive charge and accumulated on a portion of the first wafer, and a second positive charge is induced by the first negative charge and accumulated on another portion of the first wafer.

14. The etching system of claim 1, further comprising
a measurement device, configured to monitor the plurality of parameters of the etching process and transmit the plurality of parameters to the AI control module.

15. The etching system of claim 1, wherein the process chamber is further configured to execute the etching process based on the second etching recipe on a second wafer, wherein the second etching recipe is different from the first etching recipe.

16. An etching method, comprising:
obtaining a thermal image of a first wafer;
performing an etching process on the first wafer based on a first etching recipe;
determining, by an artificial intelligence (AI) control module, whether the thermal image is compliant with a predetermined requirement;
when the thermal image is not compliant with the predetermined requirement, updating the first etching recipe to generate a second etching recipe by the AI control module according to the thermal image; and
performing the etching process on a second wafer based on the second etching recipe.

17. The etching method of claim 16, wherein performing the etching process on the first wafer based on the first etching recipe comprises:
sensing a plurality of temperature information of a plurality of regions of the first wafer, respectively;
generating a plasma to etch the first wafer;
purging a heat transfer gas to control a temperature of the wafer; and
transferring a heat transfer liquid to control the temperature of the wafer.

18. The etching method of claim 17, further comprising:
monitoring a flow rate of the heat transfer liquid and a purging pressure of the heat transfer gas in real-time; and
when the thermal image is not compliant with the predetermined requirement, updating, by the AI control module, the flow rate and the purging pressure.

19. The etching method of claim 18, wherein when performing the etching process on the second wafer based on the second etching recipe is performed, the heat transfer gas is purged with the purging pressure being updated, and the heat transfer liquid is transferred with the flow rate being updated.

20. The etching method of claim 17, wherein sensing the plurality of temperature information are performed when the plasma is not generated.
